(19) United States
(12) Patent Application Publication
(10) Pub. No.: US 2013/0108064 A1
(43) Pub. Date: May 2, 2013

(54) CONNECTORS FOR INVOKING AND SUPPORTING DEVICE TESTING

(71) Applicants: Erturk D. Kocalar, Sunnyvale, CA (US); Dustin J. Verhoeve, San Francisco, CA (US); Joseph R. Fisher, JR., San Jose, CA (US); Brian J. Conner, San Jose, CA (US); Casey Hardy, San Francisco, CA (US); Adriane S. Niehaus, San Jose, CA (US); Saket R. Vora, San Francisco, CA (US)

(72) Inventors: Erturk D. Kocalar, Sunnyvale, CA (US); Dustin J. Verhoeve, San Francisco, CA (US); Joseph R. Fisher, JR., San Jose, CA (US); Brian J. Conner, San Jose, CA (US); Casey Hardy, San Francisco, CA (US); Adriane S. Niehaus, San Jose, CA (US); Saket R. Vora, San Francisco, CA (US)

(21) Appl. No.: 13/286,444

(22) Filed: Nov. 1, 2011

(51) Int. Cl. H04R 29/00; G01R 31/3187

(52) U.S. Cl. 381/58; 324/750.3

(57) ABSTRACT

Electronic devices may be provided with audio circuits and circuitry configured to support communications and test mode operations. During normal operation, a standards-compliant connector such as an audio connector may be inserted into a connector port in an electronic device. The audio connector may be associated with a headset or other accessory and may be used to carry audio signals. During test mode operations, a nonstandard test connector may be inserted into the connector port. The electronic device may detect the presence of the nonstandard connector and may direct the electronic device to operate in a testing mode.

### BACKGROUND

This relates generally to electronic devices, and, more particularly, to testing electronic devices.

Electronic devices such as media players, portable computers, and cellular telephones are generally tested during manufacturing. Testing is often performed using procedures that are compliant with the IEEE 1149.1 standard. This type of testing, which is sometimes referred to as Joint Test Action Group (JTAG) testing, can be used to capture and analyze scan chain data and perform other debug procedures.

Challenges can arise with conventional JTAG testing procedures. In some situations, it is necessary to probe a printed circuit board within a device to perform tests or to make manufacturing changes to a printed circuit board once testing is complete. Other test procedures rely on device software that is susceptible to freezing.

It would therefore be desirable to be able to provide improved techniques for testing electronic devices.

### SUMMARY

Electronic devices may be provided with audio circuits and circuitry such as controller circuitry that is configured to support communications and test mode operations. The electronic devices may have one or more ports with which external equipment may be coupled to the electronic devices.

During normal operation, a standards-compliant connector such as an audio connector may be inserted into a connector port in an electronic device. The audio connector may be associated with a headset or other accessory and may be used to carry audio signals. For example, the audio connector may have a microphone terminal for carrying microphone signals and left and right audio terminals for carrying stereo audio.

During test mode operations, a test connector that is not standards compliant may be inserted into the connector port. For example, an audio plug with a nonconducting tip region or a rotationally asymmetric audio plug with supplemental contacts may be inserted into the connector on the electronic device. Using sensors such as resistance sensors associated with the audio plug in the electronic device, the electronic device may detect the presence of the nonstandard connector and may direct the electronic device to enter test mode. During testing, test equipment that is coupled to the device using the test connector may be used in transmitting and receiving test data. Arrangements of this type may facilitate testing (e.g., JTAG testing) of enclosed electronic devices. Enclosed electronic devices may include, as examples, devices that do not include dedicated JTAG external connectors and devices in which accessing internal circuit boards for JTAG testing may require disassembly of the devices.

Further features of the invention, its nature and various advantages will be more apparent from the accompanying drawings and the following detailed description of the preferred embodiments.

### BRIEF DESCRIPTION OF THE DRAWINGS

FIG. 1 is a diagram of an illustrative system in which an electronic device and external equipment may be operated in accordance with an embodiment of the present invention.

FIG. 2 is a circuit diagram of illustrative circuitry of the type that may be used in the electronic device of FIG. 1 in accordance with an embodiment of the present invention.

FIG. 3 is a state diagram showing operations involved in monitoring whether a normal audio connector or a test audio connector has been inserted into an audio port of an electronic device in accordance with an embodiment of the present invention.

FIG. 4 is a circuit diagram showing illustrative circuitry that may be used in an electronic device that contains an audio connector, an audio circuit, and a circuit configured to support test mode operations in accordance with an embodiment of the present invention.

FIG. 5 is a diagram of an illustrative female audio connector of the type that may be used in an electronic device and an illustrative male audio connector of the type that may be coupled to the female audio connector in accordance with an embodiment of the present invention.

FIG. 6 is a cross-sectional side view of an illustrative standards-compliant audio connector inserted into a mating female audio connector in an electronic device in accordance with an embodiment of the present invention.

FIG. 7 is a cross-sectional side view of an illustrative non-standards-compliant connector arrangement that may be used to implement a test connector in accordance with an embodiment of the present invention.

FIG. 8 is a circuit diagram showing illustrative pin assignments that may be used in a circuit of the type shown in FIG. 4 in accordance with an embodiment of the present invention.

FIG. 9 is a table showing illustrative pin assignment information and sensor status as a function of different types of audio connector usage in accordance with an embodiment of the present invention.

FIG. 10 is perspective view of an illustrative rotationally symmetric standards-compliant audio connector having four contacts arranged along the length of an elongated cylindrical member in accordance with an embodiment of the present invention.

FIG. 11 is a cross-sectional side view of a connector of the type shown in FIG. 10 inserted into an electronic device audio connector of the type that is configured to mate with a rotationally asymmetric connector having segmented contacts in accordance with an embodiment of the present invention.

FIG. 12 is a perspective view of a rotationally asymmetric audio connector having segmented contacts and rotational alignment features in accordance with an embodiment of the present invention.

FIG. 13A is a cross-sectional side view of a connector of the type shown in FIG. 12 inserted into an electronic device audio connector of the type that is configured to mate with a rotationally asymmetric connector having segmented contacts in accordance with an embodiment of the present invention.

FIG. 13B is a cross-sectional side view of a connector formed in a split-cylindrical shape, having segmented contacts, and having rotational alignment features inserted into an electronic device audio connector of the type that is configured to mate with a rotationally asymmetric connector formed in a split-cylindrical shape and having segmented contacts in accordance with an embodiment of the present invention.

FIG. 14 is an end view of an illustrative audio jack and mating audio plug having rotational alignment features that have engaged one another in accordance with an embodiment of the present invention.

FIG. 15 is a cross-sectional end view of an illustrative rotationally asymmetric audio jack and mating audio connector with segmented contacts in accordance with an embodiment of the present invention.

FIG. 16 is a diagram showing how a rotationally asymmetric audio jack with four connector segments for each tip, ring, and sleeve connector and a mating audio connector may be coupled to switching circuitry that routes signals from multiple connector segments to a shared terminal for use during normal operation and to multiple test terminals for use during test mode operation in accordance with an embodiment of the present invention.

FIG. 17 is a cross-sectional end view of an audio jack having contacts that are each segmented into three parts in accordance with an embodiment of the present invention.

FIG. 18 is a flow chart of illustrative steps involved in operating a system of the type shown in FIG. 1 using connectors such as standards-compliant and non-standards-compliant audio connectors in accordance with an embodiment of the present invention.

FIG. 19A is a cross-sectional side view of a connector having eight contacts arranged along the length of an elongated cylindrical member inserted into an electronic device audio connector of the type that is configured to mate with a connector having eight contacts arranged along the length of an elongated cylindrical member and that is configured to mate with a standards-compliant audio connector having four contacts arranged along the length of an elongated cylindrical member in accordance with an embodiment of the present invention.

FIG. 19B is a cross-sectional side view of a connector having four contacts arranged along the length of an elongated cylindrical member inserted into an electronic device audio connector of the type shown in FIG. 19A in accordance with an embodiment of the present invention.

### DETAILED DESCRIPTION

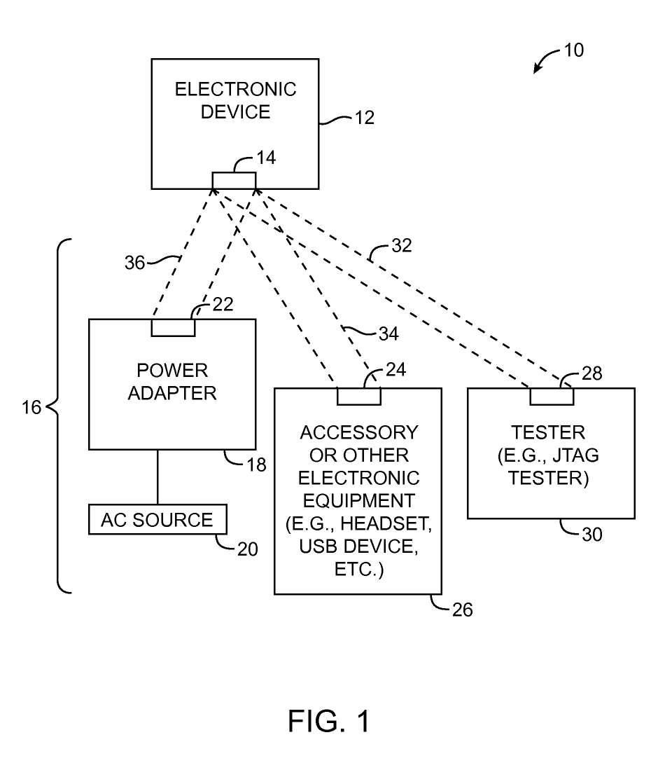

Electronic devices may be provided with circuitry that supports testing. An illustrative system environment for a device that has circuitry that supports testing is shown in FIG. 1. As shown in FIG. 1, system 10 may include an electronic device such as electronic device 12. Electronic device 12 may be a portable electronic device or other suitable electronic device. For example, electronic device 12 may be a laptop computer, a tablet computer, a somewhat smaller device such as a wrist-watch device, pendant device, headphone device, earpiece device, or other wearable or miniature device, a cellular telephone, a media player, larger devices such as desktop computers, computers integrated into computer monitors, or other electronic devices.

Device 12 may include a connector such as connector 14. Connector 14 may have two contacts, three contacts, four contacts, five contacts, six contacts, six or more contacts, six or fewer contacts, seven contacts, seven or more contacts, seven or fewer contacts, thirty contacts, or any other suitable number of contacts.

Connector 14 may be coupled to different types of external equipment. As shown in FIG. 1, external equipment 16 of the type that may be connected to device 12 may include power supplies such as power adapter 18, accessories such as accessory 26, and testers such as tester 30 (as examples).

Power adapter 18 may convert alternating current power from alternating current (AC) source 20 into direct current (DC) signals at connector 22. When it is desired to charge a battery in device 12 or to otherwise provide power to device 12, power adapter connector 22 may be connected to mating electronic device connector 14, as illustrated by path 36.

Accessory 26 may include a connector such as connector 24 that mates with connector 14. Accessory 26 may be a mono or stereo headset with a microphone, a mono or stereo headset without a microphone, a charging station, an external set of speakers, a computer (e.g., a laptop or desktop computer that is being used to provide power to device 12 and/or that is being used to synchronize data with device 12), or other suitable accessories or external equipment. When it is desired to use accessory 26 with device 12, accessory connector 24 may be plugged into connector 14 of electronic device 12, as indicated by path 34.

Testing may be performed using tester 30. Tester 30 may be a Joint Test Action Group (JTAG) tester or test equipment that supports other testing protocols. JTAG testers sometimes use four or five pin interfaces (e.g., interfaces that include pins such as a JTAG test data input pin TDI, a JTAG test data output pin TDO, a JTAG clock pin TCK, a JTAG state machine control pin TMS, and, if desired, a reset pin). In some test environments, it may be desirable to minimize pin counts, so protocols such as the Serial Wire Debug (SWB) protocol have been developed that support testing over two pins (e.g., using a SWDIO data pin and a clock pin SWCLK). Serial Wire Debug interfaces can be used to support JTAG testing. Illustrative configurations in which tester 30 is a tester of the type that may support JTAG and/or Serial Wire Debug testing are sometimes described herein as an example. In general, however, tester 30 may support any suitable test protocols. As shown by path 32, test connector 28 of tester 30 may be mated with connector 14 of electronic device 12 when it is desired to test device 12.

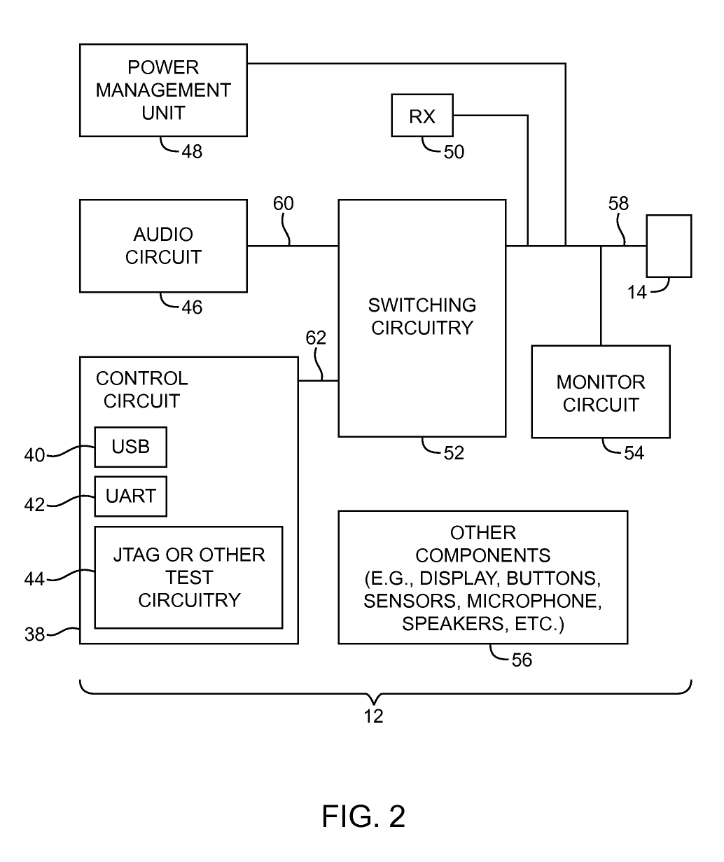

Illustrative circuitry that may be provided in electronic device 12 is shown in FIG. 2. As shown in FIG. 2, a path such as path 58 may be coupled to connector 14. Path 58 may include conductive traces on a printed circuit board or other substrate. Components such as integrated circuits, switches, sensors, and other devices may be mounted on the substrate. The traces or other conductive lines in path 58 may each be connected to a respective contact in connector 14. If, for example, connector 14 contains four contacts, each of the four contacts may be connected to a respective line in path 58.

Device 12 may use a monitor circuit such as monitor circuit 54 to monitor the status of connector 14. For example, monitor circuit 54 may monitor the contacts of connector 14 for the presence of a signal or connector characteristic that indicates that device 12 should enter a testing mode (e.g., a JTAG mode).

Switching circuitry 52 may be used to selectively couple the lines in communications path 58 to lines such as lines in paths 60 and 62. For example, during normal operation of device 12 by a user, switching circuitry 52 may be configured to route signals from connector 14 to audio circuit 46 using two or more lines in path 60. During test mode operations, switching circuitry 52 may be configured to route signals from connector 14 to test module 44 of control circuitry 38 via two or more lines in path 62.

Audio circuit 46 may be, for example, an audio integrated circuit that handles analog and/or digital audio signals. Functions such as media playback, microphone signal amplification, noise cancellation, digital-to-analog and analog-to-digital conversion, equalization, volume control, pin assignment swapping (e.g., to accommodate headsets in which the microphone and ground terminals are reversed), and other control and audio processing features may be handled by audio circuit 46. In some contexts, audio circuit 46 may be referred to as a codec. Non-audio functions may, if desired, be integrated into audio circuit 46 or provided using other circuits in device 12.

Control circuit 38 may be implemented using one or more integrated circuits. Control circuit 38 may, for example, be implemented using an integrated circuit of the type that is sometimes referred to as a system-on-a-chip (SOC) integrated circuit. System-on-a-chip integrated circuits generally include a processor and other circuits. Control circuit 38 may include memory or may be coupled to external storage (e.g., memory in components 56).

Control circuit 38 may include processing circuits such as one or more testing and communications modules. As an example, control circuit 38 may include a communications module such as Universal Serial Bus (USB) module 40, a communications module such as Universal Asynchronous Receiver Transmitter (UART) module 42, and other communications circuits. Control circuit 38 may include testing circuitry 44. Testing circuitry 44 may support test protocols such as four or five wire JTAG protocols and/or protocols in which JTAG data is conveyed use a two-wire test interface such as a Serial Wire Debug interface.

Power management unit 48 may be used to handle operations associated with receiving external power through connector 14. For example, when power adapter 18 (FIG. 1) is coupled to connector 14, power management unit 48 may be used in routing the power from power adapter 18 to a battery within device 12 when the battery is in need of charging. Power management unit 48 may also route power to internal circuitry within device 12 when it is desired to power device 12 directly from externally supplied DC signals.

Accessories 26 (FIG. 1) such as headsets may include antennas. For example, wiring within a headset may serve as a frequency modulation (FM) antenna for device 12. Receiver circuitry 50 within device 12 can receive FM signals from the antenna via connector 14 and path 58.

Device 12 may contain other components 56. Components 56 may include one or more displays, status indicator lights, buttons, sensors, microphones, speakers, a battery, amplifiers, radio-frequency transceiver circuits, microprocessors, microcontrollers, volatile memory (e.g., dynamic random-access memory, static random-access memory, etc.), non-volatile memory (e.g., flash memory or other solid state storage), hard drives, application-specific integrated circuits, and other electrical components. These components may be interconnected with the other components shown in FIG. 2. For example, one or more rigid printed circuit boards (e.g., fiberglass-filled epoxy printed circuit boards) and/or flexible printed circuits (e.g., flex circuits formed from patterned conductive traces on flexible sheets of polyimide or other polymers) may serve as substrates onto which the components of FIG. 2 may be mounted. The storage and processing circuitry in device 12 such as the non-volatile and volatile memory in device 12, control circuit 38, microprocessor circuitry, and processing circuitry in application-specific integrated circuits in device 12 form control circuitry that can be used in running software for device 12, controlling the operation of switching circuitry 52 and other components 56 in device 12, etc.

To ensure that device 12 enters a JTAG test mode or other desired testing mode, device 12 may be provided with external input. The external input may take the form of insertion of a predefined connector into connector 14, signals that are supplied to connector 14 by tester 30, and/or other suitable input for directing device 12 to enter a test mode of operation.

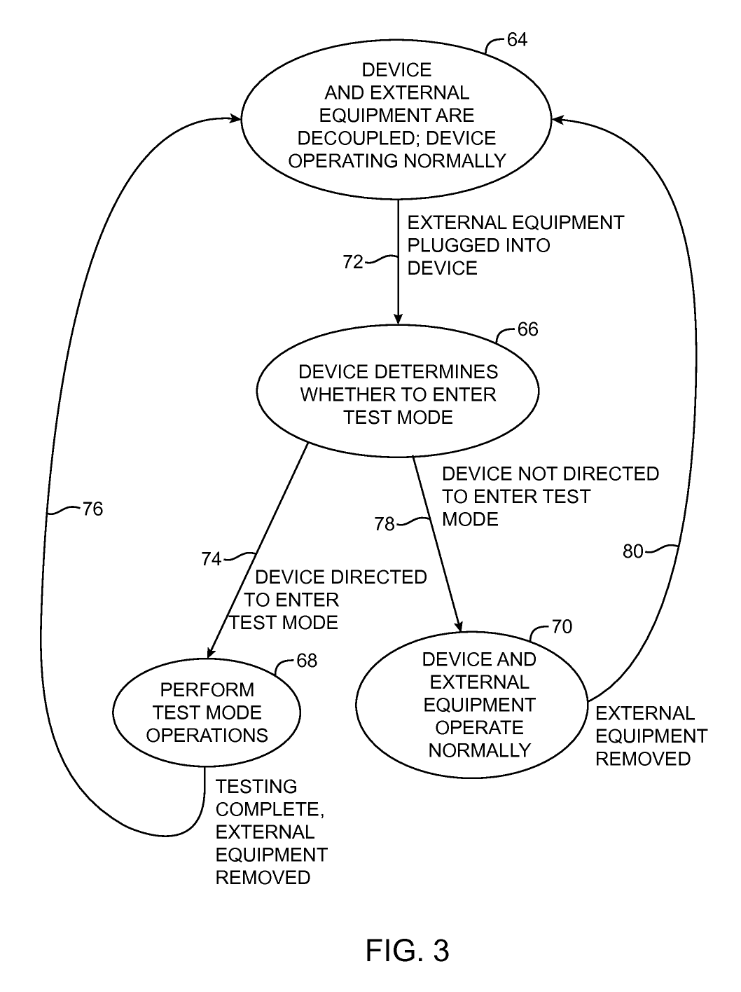

A state diagram showing operations involved in using device 12 in a system environment such as system 10 of FIG. 1 is shown in FIG. 3. During the operations of state 64, device 12 is disconnected from external equipment 16. In particular, device 12 is not connected to any accessories 26, device 12 is not connected to power adapter 18, and device 12 is not connected to tester 30.

As indicated by line 72, when a piece of external equipment 16 is plugged into device 10, device 12 may perform operations to determine whether to enter test mode (state 66). These operations may include, for example, using monitor circuit 54 to measure signals on the contacts of connector 14. Signal measurements may be made, for example, to compare the signals on the contacts to reference signals (e.g., to compare signal voltages to reference voltages), to compare the magnitudes of the signals to each other (e.g., to compare signal voltages on one or more contacts to signal voltages on one or more other contacts), to compute resistances, to evaluate the states of sensors that monitor whether a connector is plugged into connector 14, etc.

In response to a determination by device 12 that device 12 is not being instructed to enter test mode (i.e., because the external equipment that was connected to device 12 was a power adapter or other accessory and not a tester), device 12 may transition to state 70, as indicated by line 78. During the operations of state 70, device 12 and the external equipment that is connected to device 12 (e.g., power adapter 18 or other accessories such as accessory 26) may be operated normally. Once the external equipment is removed, device 12 may transition back to state 64, as indicated by line 80.

In response to a determination by device 12 that device 12 is being instructed to enter test mode (i.e., because the external equipment that was coupled to device 12 was a tester such as tester 30), device 12 may transition to state 68 (test mode), as indicated by line 74. During state 68, test circuitry 44 may be activated and used for handling test operations. For example, JTAG circuitry may be used to perform boundary scan test operations, may be used in conveying test data to tester 30, and may be used in performing other test operations for testing whether device 12 is operating satisfactorily. If errors are identified, a test operator may be alerted (e.g., by displaying an alert message on tester 30). Debugging operations may be performed in which test data captured by circuitry 44 is transmitted to tester 30 for analysis. Tester 30 may also direct the components of device 12 to perform various actions (e.g., adjusting integrated circuit settings, etc.) and may evaluate the ability of device 12 to execute these actions.

Once testing has been completed, tester 30 may be disconnected from connector 14 and, as indicated by line 76, device 12 may be operated while being decoupled from external equipment (state 64).

Switching circuitry 52 may contain electronic switches that are controlled by control signals from control circuitry in device 12 (e.g., control circuit 38 and/or other storage and processing circuitry in device 12). Switches within switching circuitry 52 may be based on transmission gates (e.g., gates based on metal-oxide-semiconductor transistors) or other electrically controllable switch technologies.

There may be any suitable number of switches in switching circuitry 52 (e.g., one or more, two or more, five or more, ten or more, etc.). The number of switches that are used in switching circuitry 52 may be selected to provide a desired amount routing flexibility for signals within device 12. For example, if it is desired to be able to route a set of audio signals from connector 14 to audio circuit 46 in either normal or reversed configuration (e.g., to accommodate normal and reversed microphone/ground line pin assignments in connector 14), switching circuitry 52 may be provided with sufficient switching resources to route the microphone and ground contacts in connector 14 to a pair of respective pins in audio circuit 46 in a normal configuration or in a configuration in which the signals are reversed).

As another example, if it is desired to route signals from a contact in connector 14 to several possible destinations such as a pin in audio circuit 46, a pin associated with USB module 40, a pin associated with UART module 42, and a pin associated with test circuitry 44, switching circuitry 52 may be provided with switches for forming a multiplexing circuit that is capable of selecting which of these various paths should be formed in device 12. Configurations for switching circuitry 52 that include relatively more switches may be used to provide enhanced amounts of interconnection flexibility, whereas configurations for switching circuitry 52 that include relatively fewer switches may be used to conserve device resources.

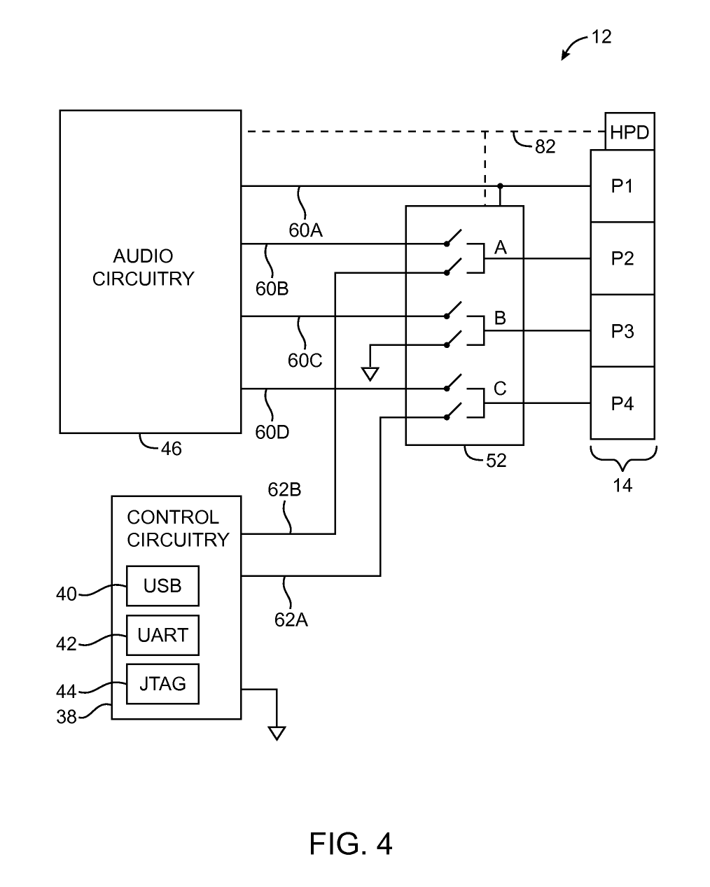

FIG. 4 is a circuit diagram showing an illustrative configuration that may be used for electronic device 12 in which switching circuitry 52 includes at least three sets of switches. Connector 14 in the example of FIG. 4 has four contacts (pins P1, P2, P3, and P4). Signals from contact P2 may be routed to audio circuitry 46 via path 60B or control circuitry 38 via path 62B using switching circuitry A. Signals from contact P3 may be routed to audio circuitry 46 via path 60C or to control circuitry 38 via path 62A using switching circuitry B. Switching circuitry C may be used to route signals from contact P4 to audio circuitry 46 via path 60D or to control circuitry 38 via path 62A. Using a switching scheme of the type shown in FIG. 4, signals may, if desired, be routed to audio circuitry 46 and control circuitry 38 simultaneously from a given contact in connector 14. If desired, switching circuitry 52 may contain switches that only allow signals to be routed to audio circuitry 46 or control circuitry 38, but not both simultaneously. The arrangement of FIG. 4 is merely illustrative.

Switching circuitry 52 and audio circuitry 46 or other circuitry in device 12 may, if desired, receive a signal from connector 14 via path 82. This signal may be used in connection with the signal on path 60A to determine whether a mating connector has been inserted into connector 14 in the position associated with contact P1. Consider, as an example, a configuration in which contact 14 is a four pin female audio connector (sometimes referred to as an audio jack). This type of connector, which is sometimes referred to as a TRRS (tip-ring-ring-sleeve) connector, may use contact P1 to mate with a corresponding tip contact in a four-pin male audio connector (sometimes referred to as an audio plug), may use contact P2 to mate with a first corresponding ring contact in a four-pin male audio connector, may use contact P3 to mate with a second corresponding ring contact in a four-pin male audio connector, and may use contact P4 to mate with a sleeve contact in a four-pin male audio connector.

The tip contact (pin P1) may be associated with a left audio channel, the first ring contact (pin P2) may be associated with a right audio channel, the second ring contact (pin P3) may be associated with an audio ground, and the sleeve contact (pin P4) may be associated with a microphone contact. In some locations, convention may dictate that the microphone and ground pins are reversed. This pin reversal situation can be accommodated using switching circuitry 52 and/or automatic switching circuitry in audio circuit 46. In non-audio applications (e.g., when conveying test signals to testing circuitry 44 and/or other circuits such as circuits 40 and 42 of FIG. 4), the pins in contact 14 may be used to carry other signals.

To detect whether the tip of an audio plug has been received properly within the tip portion of the audio jack (connector 14), connector 14 may be provided with a sensor that detects the presence (absence) of the audio plug tip portion in the vicinity of contact P1. A mechanical sensor, optical sensor, electrical sensor, or any other suitable type of sensor may be used to detect the presence of all or part of an audio plug within connector 14.

As one example, a tip sensor (sometimes referred to as a headphone detect sensor) may be implemented by measuring the resistance between a pair of contacts associated with pin P1. The first contact may be, for example, pin P1 itself and the second contact (illustrated as contact HPD in FIG. 4) may be an ancillary contact that is configured to form an electrical connection with a properly positioned tip connector on an inserted audio plug. Control circuitry in device 12 (e.g., headphone detection circuitry in switching circuitry 52, audio circuitry 46, control circuitry 38, or other control circuitry in device 12) may be used in evaluating the resistance between contacts HPD and P1 in real time.

When the measured resistance between sensor contacts HPD and P1 is relatively high (e.g., over a predefined threshold level), it can be assumed that the tip contact portion of the male audio connector is not present. When the measured resistance between HPD and P21 is low (e.g., below the predefined threshold level), device 12 can conclude that the tip contact from the audio plug has been inserted into connector 14 (e.g., the audio plug is present). Different actions can be taken depending on whether or not the audio tip is present (e.g., actions related to configuring switching circuitry 52 and/or using audio circuitry 46 and/or circuitry such as control circuitry 38).

In the example of FIG. 4, path 82 and path 60A are coupled to circuitry 46 and circuitry 52, illustrating how circuitry 46 and/or circuitry 52 may be used in monitoring the resistance between contacts HPD and P1 to determine whether or not the tip of an audio plug has been received within connector 14. If desired, control circuitry 38 or other control circuitry in device 12 may be used to measure the resistance between HPD and P1 to detect the presence of the audio plug tip.

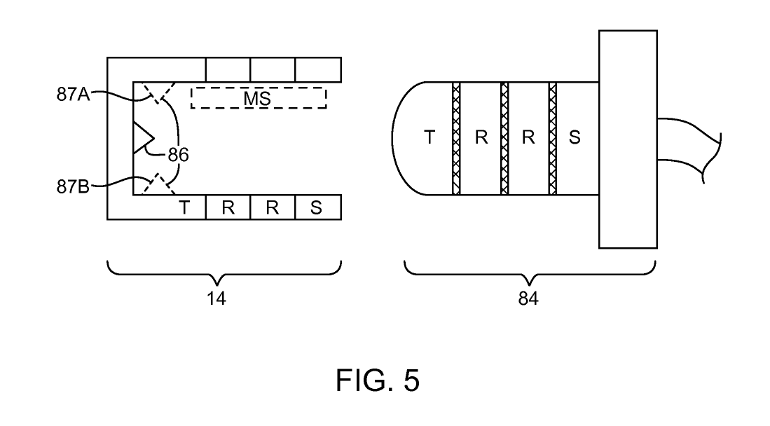

FIG. 5 is a cross-sectional side view of a connector such as connector 14 of device 12 in a configuration in which connector 14 has been implemented using an audio connector with four contacts (T, R, R, and S). If desired, connector 14 may be a three-pin audio connector (e.g., a TRS connector). The example of FIG. 5 in which connector 14 is a four-pin (TRRS) audio connector is merely illustrative.

Connector 14 may be an audio jack that mates with corresponding audio plugs such as audio plug 84. Audio plug 84 may be associated with any suitable type of external equipment 16. For example, audio plug 84 may serve as connector 22 of power adapter 18, connector 24 of accessory 26, or connector 28 of tester 30 (FIG. 1).

Optional contact 86 may serve as contact HPD of FIG. 4. Control circuitry in device 12 can monitor the resistance between terminals T and 86 to determine when an audio plug is inserted into connector 14. Other sensors (e.g., sensors associated with terminals R, R, and S, mechanical sensors such as sensor MS that can detect whether connector 84 has been inserted into connector 14 or other sensors) may be used in monitoring the status of connector 84 and connector 14.

As shown in FIG. 5, connector 14 may include one or more contacts 86. Contacts 86 may be provided at one or more locations within connector 14. As examples, contact 86 may be located along the center axis of connector 14 (as shown by the solid version of contact 86) and one or more contacts 86 may be located across from tip contact T of connector 84 when connector 84 is inserted into connector 14(as shown by dashed version 87A and 87B of contact 86). Arrangements in which contact 86 is located in positions such as positions 87A an 87B may facilitate detection of split plugs 84 (e.g., plugs formed from half of a cylinder).

If desired, the type of connector that is used by testers such as tester 30 may be different from the type of connector that is associated with other types of external equipment 16. When a connector is plugged into connector 14 in device 12, device 12 can determine which type of connector has been plugged into connector 14 and can respond accordingly. As an example, equipment 16 such as adapter 18 and accessories 26 may use standard (i.e., standards-compliant) four-pin audio plugs. These four-pin audio plugs may each contain a tip contact. Tester 30 may use a modified version of an audio plug that omits the tip contact (as an example). When the tipless audio plug is inserted into connector 14 of device 12, device 12 may be forced into a testing mode (e.g., a JTAG mode) by circuitry 38, even if software running on device 12 (e.g., software running on a microprocessor in components 56) has frozen and is not available to recognize button presses or other commands for initiating testing.

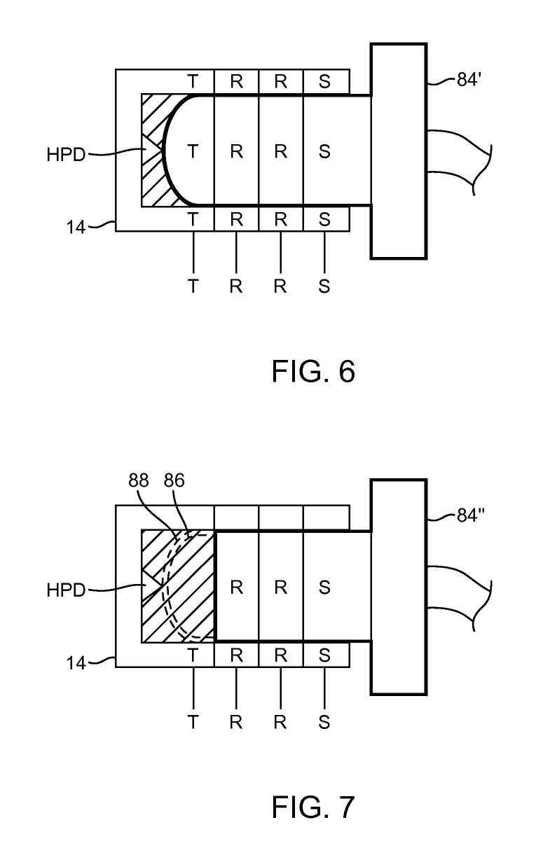

FIG. 6 is a cross-sectional side view of an illustrative configuration in which connector 14 for device 12 has been provided with a contact (contact HPD) for use in detecting the presence of tip contact T in audio plug 84′. Control circuitry in device 12 may monitor the resistance between contact HPD and contact T in connector 14. If tip T is present in audio connector 84′ of FIG. 6, the measured resistance between HPD and tip T in connector 14 will be low (i.e., HPD and contact T in connector 14 will be shorted together).

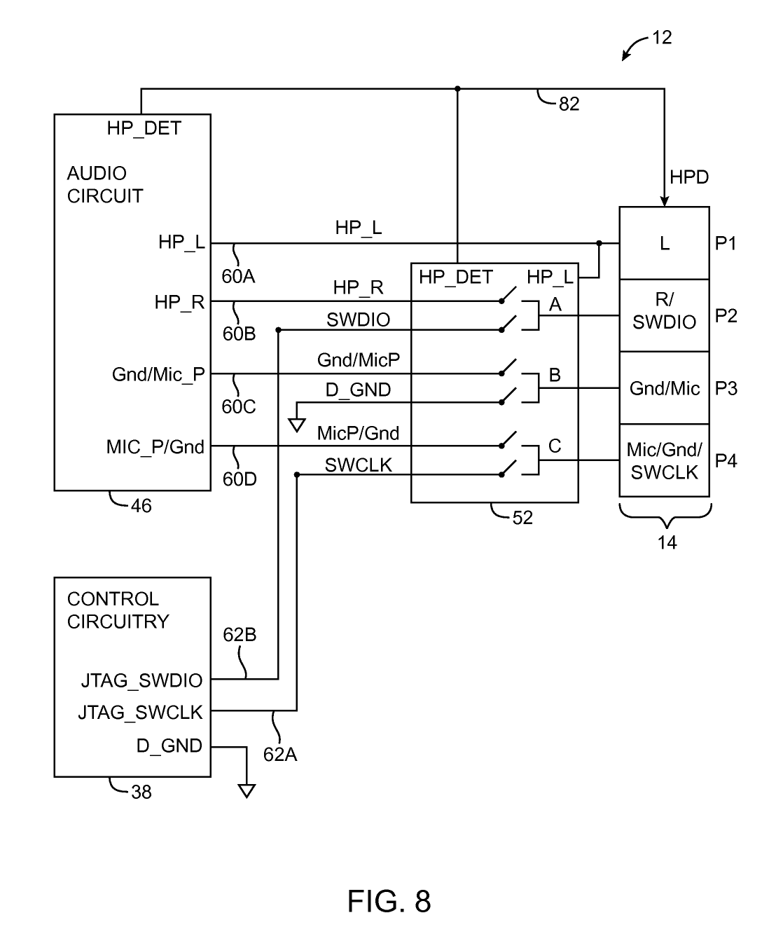

FIG. 7 is a cross-sectional side view of an illustrative configuration in which a tipless audio plug (i.e., an audio plug with a nonconducting tip structure) such as tipless audio plug 84″ has been inserted into connector 14. Because the tip contact that would normally be present in a standard TRRS audio plug such as TRRS audio plug 84′ of FIG. 6 is not present in plug 84″ of FIG. 7, no low-resistance electrical path between terminals HPD and T in connector 14 is formed (i.e., terminals HPD and T will form an open circuit). A mechanical sensor such as sensor MS of FIG. 5 or other sensor may be used by device 12 to determine whether or not an audio plug has been inserted into connector 14. When device 12 determines that an audio plug (e.g., plug 84″ of FIG. 7) has been inserted into connector 14 and measures a high impedance (open circuit) between terminals HPD and T in connector 14, device 12 can enter testing mode operations (e.g., using JTAG test circuitry 44).

If desired, connector 84″ can include an insulated tip connector portion such as insulated tip portion 86. Tip portion 86 may be coated with an insulating layer (e.g., a layer of plastic or other dielectric coating) such as layer 88. As with the missing tip configuration, a high-impedance (open circuit) will be measured between terminals HPD and T of connector 14 when audio plug 84″ is inserted into connector 14.

The ability to force device 12 into a testing mode (e.g., JTAG testing, Serial Wire Debug testing, etc.) using a non-standard connector (e.g., a tipless connector, an insulated tip connector or other connector without a conductive tip, or other suitable modified connector) may be advantageous when evaluating devices that are prone to freezing when running test software. Devices under test whose state has become frozen when running test software may become unresponsive to button presses and other conventional actions for invoking testing. By using the non-standard connector, a frozen device can be forced into test mode, so that test data from test circuitry 44 can be gathered and evaluated by tester 30. In test mode, device 12 and tester 30 can exchange test data through connector 12 and a mating test connector such as connector 84″ of FIG. 7. In configurations for tester 30 in which the pin count of the tester's connector (e.g. connector 84″ of FIG. 7) is relatively low (e.g., two or three contacts), it may be desirable to use a test such as the Serial Wire Debug protocol that can convey signals using relatively few pins (e.g., two pins). Testers can also be provided with non-standard connectors that use an audio-plug form factor, but which contain additional contacts.

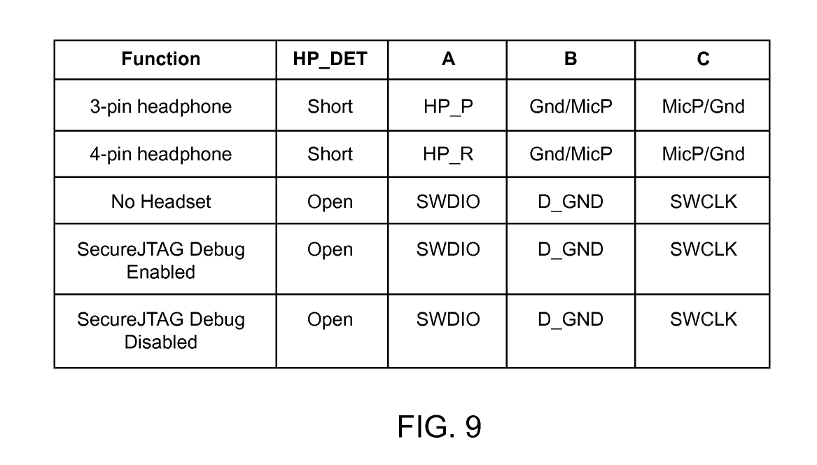

FIG. 8 is a circuit diagram showing illustrative pin assignments that may be used in a circuit arrangement of the type shown in FIG. 4. As shown in FIG. 8, contact P1 of connector 14 may be associated with a left channel of audio L. Contact P2 of connector 14 may be associated with a right channel of audio R during normal operation. During testing (e.g., JTAG testing), contact P2 may be associated with a signal SWDIO (e.g., a first of two Serial Wire Debug signals). During normal operation, contact P3 may be associated with ground and contact P4 may be associated with a microphone signal from a microphone in an attached accessory (e.g., a headset with a microphone or other accessory 26). In some geographic regions, convention may dictate that the normal pin assignments for contacts P3 and P4 be reversed (i.e., so that contact P3 is used for microphone signals and so that contact P4 serves as a ground terminal). During testing, contact P4 may be associated with a signal SWCLK (e.g., a second of two Serial Wire Debug signals). The signals SWDIO and SWCLK may, if desired, form a testing interface that is used for handling JTAG test data, so when routed to control circuitry 38 via switching circuitry 52 and paths 62A and 62B (e.g., in response to detection of a non-standard plug in connector 14), signals SWIDO and SWCLK may be referred to as JTAG_SWDIO and JTAG_SWCLK as shown in FIG. 8.

The presence or absence of a conductive tip in the connector that is plugged into connector 14 of device 12 can be detected by measuring the impedance between headphone detection terminal HPD (headphone detection signal HP_DET) and line HP_L. In response to detection of a plug in connector 14 in the absence of a short circuit between HP_DET and HP_L device 12 can conclude that a non-standard (test) version of the audio plug such as plug 84″ has been inserted into connector 12.

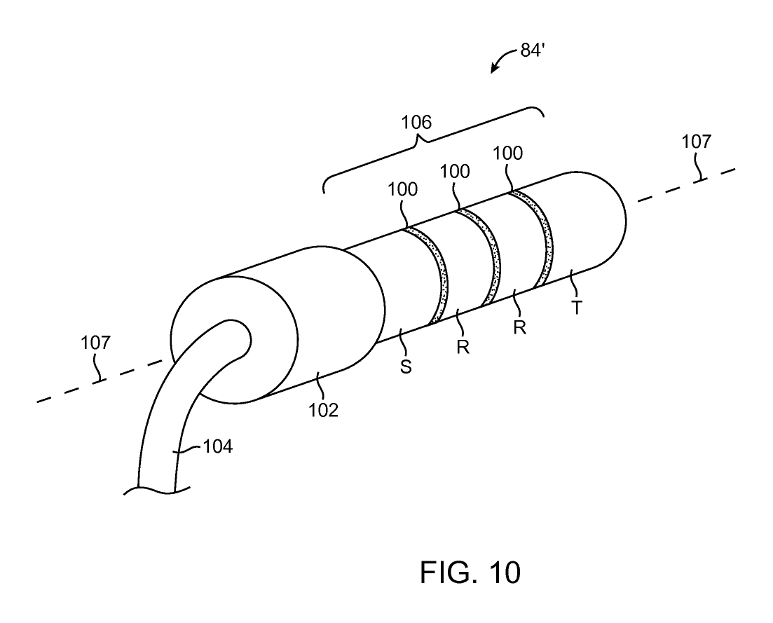

FIG. 9 is a table showing how various audio and test signals can be routed through switching circuitry 52 in various inserted plug scenarios. In normal operation, a standard three-pin audio plug may be plugged into connector (the first row of the table of FIG. 9) or a standard four-pin audio plug may be plugged into connector 14 (the second row of the table of FIG. 9). In either of these scenarios, the tip portion of the inserted plug will lead to a “short” condition for headphone detection signal HP_DET. When no audio plug is inserted, the signal HP_DET will become open (the third row of the table of FIG. 9).

During testing, a non-standard audio plug that does not have a conductive tip can be inserted into connector 14, leading the HP DET signal to be “open,” as shown in the fourth and fifth rows of the table of FIG. 9. To enhance security and prevent attackers from gaining access to JTAG functions or other test functionality in circuitry 38, circuitry 38 can require authentication before permitting access to the test functionality of circuitry 38. For example, tester 30 may be required to authenticate using a Secure JTAG protocol before being permitted to interact with JTAG testing circuitry 44 (FIG. 2).

Use of a radially symmetric test connector such as connector 84″ of FIG. 7 may limit the number of test signals that can be conveyed between tester 30 and device 12 during testing. For example, if non-standard connector 84″ is based on a three pin connector, there may only be two pins remaining following insulation of the tip portion of the connector, whereas a four-pin audio plug with a non-standard insulated or missing tip may only be able to convey three different signals.

Some protocols may involve the use of more signals. For example, a four-contact or five-contact connector may be desired for simultaneously handling signals from four or five JTAG pins in tester 30. To accommodate these additional test signals, test connector 28 may be provided with additional contacts. To ensure compatibility between standard connectors and connector 12, connector 12 can be configured for backwards compatibility. In particular, connector 12 may be configured to operate as a normal audio plug during normal operations (e.g., when receiving a four-pin audio plug), while making additional contacts available during testing (e.g., when receiving a non-standard audio plug).

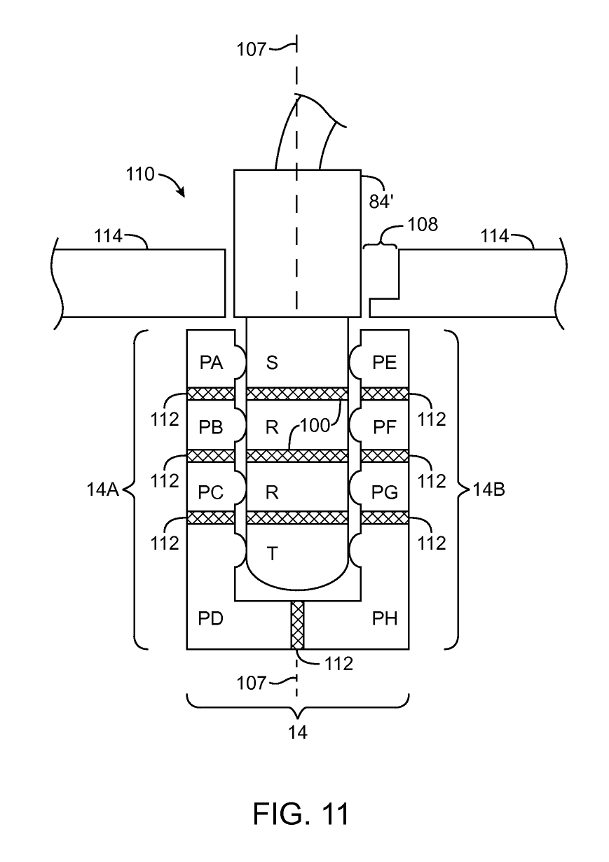

FIG. 10 is a perspective view of a four-pin audio connector (i.e., a standards-compliant four-pin audio plug such as a ⅛″ TRRS connector) of the type that may be used as connector 22 in power adapter 18 or connector 24 in accessory 26. As shown in FIG. 10, audio plug 84 may have an elongated plug portion 106 having a tip contact T, first and second ring contacts R, and sleeve contact S, separated by respective insulating regions 100. Plug body 102 and cable 104 (e.g., a four-wire cable having conductive lines connected respectively to the four contacts in connector 84′) may be coupled to elongated plug portion 106. The contacts in elongated portion 106 of plug 84′ may be rotationally symmetric (i.e., symmetric when rotated around longitudinal axis 106 of elongated portion 106).

To provide a test plug with additional contacts, a test plug may be configured to use a rotationally asymmetric layout for its contacts. Connector 14 may be provided with a corresponding pattern of rotationally asymmetric contacts. When mated with a rotationally symmetric connector such as rotationally symmetric four-contact audio plug 84′ of FIG. 10, the rotationally asymmetric version of connector 14 can gather signals from each of the four contacts in audio plug 84′.

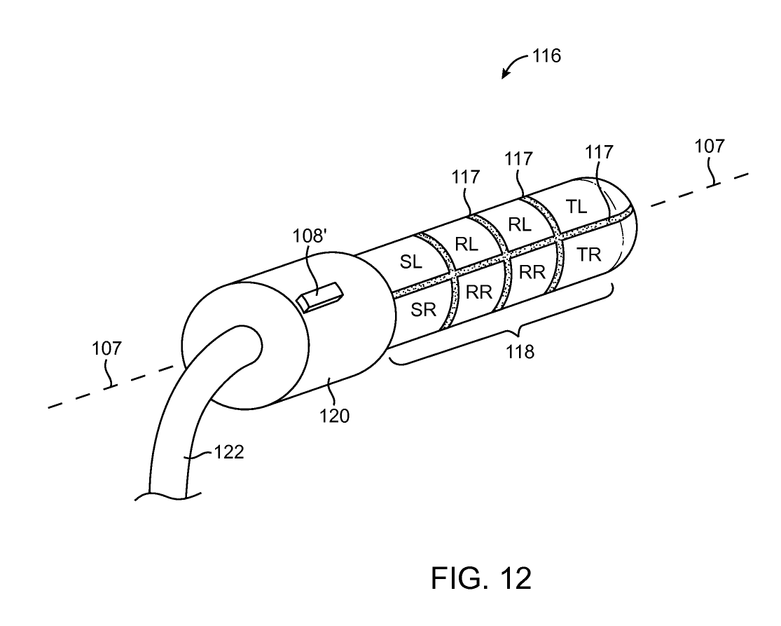

A cross-sectional side view of a rotationally symmetric audio plug such as plug 84′ of FIG. 10 that has been inserted into a rotationally asymmetric connector in device 12 is shown in FIG. 11. As shown in FIG. 11, rotationally asymmetric connector 14 may have connector portions 14A and 14B on opposing sides of longitudinal axis 107. Portion 14A of connector 14 may include tip contact PD, ring contacts PC and PB, and sleeve contact PA. Portion 14B of connector 14 may include tip contact PH, ring contacts PG and PF, and sleeve contact PE. Contacts PD and PH may be separated from each other by insulating material 112. Insulating material 112 may also be used in separating the other contacts in portions 14A and 14B from each other.

Each of the eight contacts in connector 14 of FIG. 11 may be monitored by the control circuitry of device 12. When a standard (rotationally symmetric) audio plug such as plug 84′ is mated with connector 14, the contacts of portion 14A, the contacts of portion 14B, or the contacts in portions 14A and 14B in parallel may be used in handling the signals for plug 84′.

Device 12 may have a housing such as housing 114. Housing 114 may be formed from metal, plastic, fiber-composite materials, glass, ceramic, other materials, or combinations of these materials. Housing 114 may have an opening such as opening 110. Opening 110 may be, for example, a circular opening that allows plug 84′ to be received within connector 14. Connector 14 may be, for example, a cylindrical connector. Portions of housing structures 114 or other portions of device 12 that are located in the vicinity of connector 14 or that are formed as part of connector 14 may be used to form rotational alignment structures (feature) such as rotational alignment structure 108. In the FIG. 11 example, rotational alignment structure 108 is formed from a notch-shaped indentation in housing wall 114. Other configuration may be used for rotational alignment structures if desired. Rotational alignment features may, for example, be formed using grooves, notches,

Rotationally symmetric audio plugs such as audio plug 84′ of FIG. 11 need not have features that mate with rotational alignment features 108 of connector 14, because the rotational symmetry of such plugs ensures that each of the contacts in the plug will make contact with appropriate contacts in connector 14.

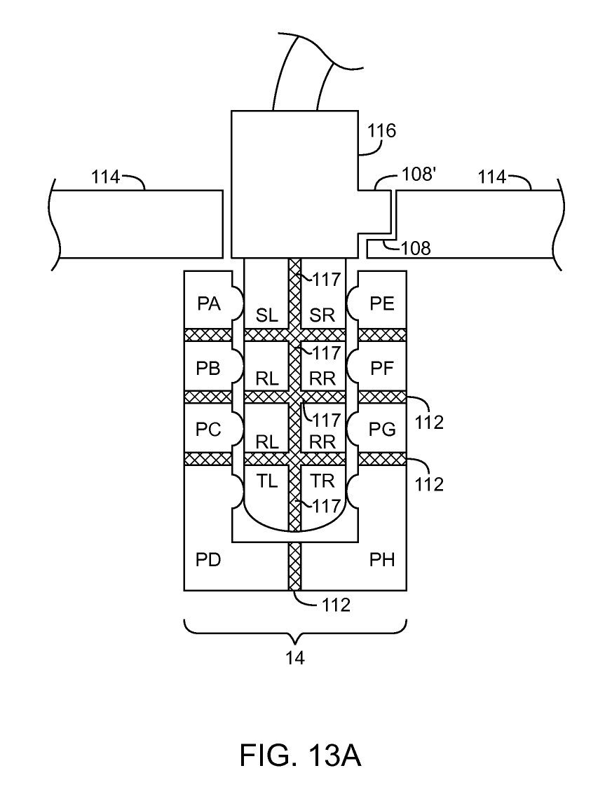

When inserting an asymmetric audio plug into connector 14, however, a mating rotational alignment feature on the audio plug may be used to ensure that the contacts of the plug mate with the associated contacts in contact 14. FIG. 12 is a perspective view of an illustrative rotationally asymmetric connector of the type that may be used for connector 28 of tester 30. As shown in FIG. 12, rotationally asymmetric connector 116 is rotationally asymmetric with respect to rotational axis 107 (i.e., the longitudinal axis of elongated cylindrical member 118 of connector 116). There may be eight contacts on member 118 such as tip contact TL, ring contacts RL, and sleeve contact SL on one side of portion 118 and tip contact TR, ring contacts RR, and sleeve contact SR on an opposing side of portion 118. These contacts may be formed by segmenting the tip, ring, ring, and sleeve contacts on an audio connector to form additional contacts. Insulator 117 may be used to separate the contact segments from each other. Body portion 120 of connector 116 or other structures on connector 118 may be provided with rotational alignment features such raised ridge 108′ or other suitable rotational alignment structures (e.g., notches, protrusions, ridges, recesses, etc.). Cable 122 (e.g., an eight-wire cable having eight conductive wires that are respectively connected to the eight contacts of portion 118 of plug 116) may be coupled to plug 116 using body portion 120 of plug 116.

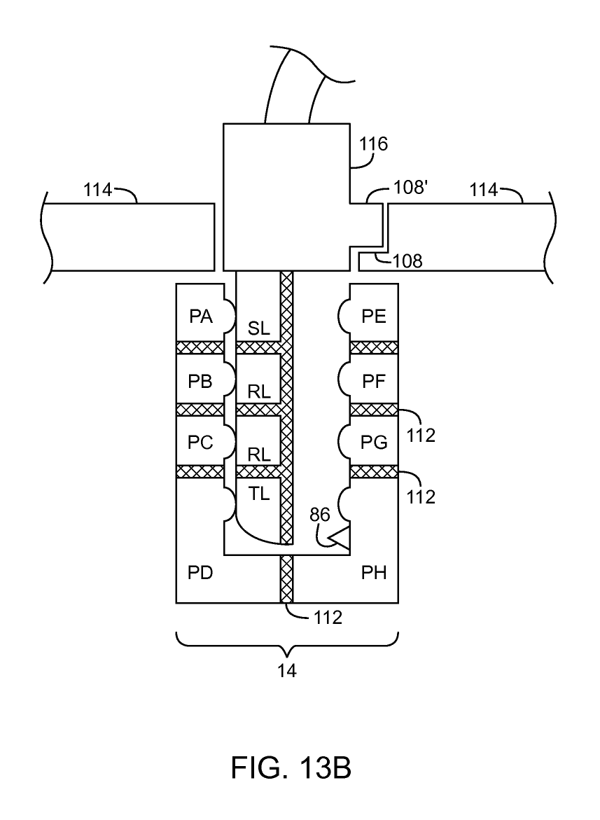

A cross-sectional side view of a rotationally asymmetric connector such as rotationally asymmetric connector 14 of FIG. 11 in a configuration in which rotationally asymmetric plug 116 has been inserted into connector 14 so that the contacts of plug 116 have mated with respective contacts in connector (jack) 14 is shown in FIG. 13A. As shown in FIG. 13A, when audio plug (male audio connector) 116 has been inserted into audio jack (female audio connector) 14, each of the contacts on plug 116 mates with a corresponding one of the contacts on connector 14. In particular, tip contact TL on plug 116 forms an electrical connection with contact PD of connector 14, ring connectors RL on plug 116 form contacts with respective contacts PB and PC. Sleeve contact SL forms an electrical connection with contact PA of connector 114. Tip contact TR on plug 116 mates with contact PH on connector 114. Contacts RR on plug 116 are electrically shorted to respective contacts PF and PG on plug 116 and contact SR on plug 116 makes contact with contact PE of connector 114.

Because there are eight independent contacts on plug 116 and eight corresponding independent contacts on connector 14, eight separate electrical pathways may be formed between tester 30 and device 12. These eight communications paths may be used for conveying four or five JTAG signals (and, if desired, three or four other signals), may be used for carrying Serial Wire Debug traffic, or may be used in handling other testing signals. Test connectors with more than eight separate contacts or with fewer than four contacts may also be used (e.g., male and female rotationally asymmetric connectors with 2-5 contacts each, with 2-8 contacts each, with 5-8 contacts each, with more than 4 contacts each, with more than 6 contacts each, etc.).

As shown in FIG. 13B, plug 116 may be formed in a split-cylindrical shape in at least some suitable arrangements. As an example, plug 116 of FIG. 13B may include tip contact TL, ring contacts RL, and sleeve contact SL, but may not include tip contact TR, ring contacts RR, and sleeve contact SR, which may form part of plug 116 of FIG. 13A. If desired, audio jack 14 may include one or more optional contacts 86 (e.g., in the location illustrated in FIG. 13B) that may be capable of detecting plugs 116 and that may be capable of differentiating between full-cylindrical plugs 116 (of the type shown in FIG. 13A) and split-cylindrical plugs 116 (of the type shown in FIG. 13B). In particular, because of rotational alignment structures 108 and 108′, split-cylindrical plugs 116 may not contact optional contact 86 (e.g., when contact 86 is positioned as shown in FIG. 13B) while full-cylindrical plugs 116 may contact optional contact 86.

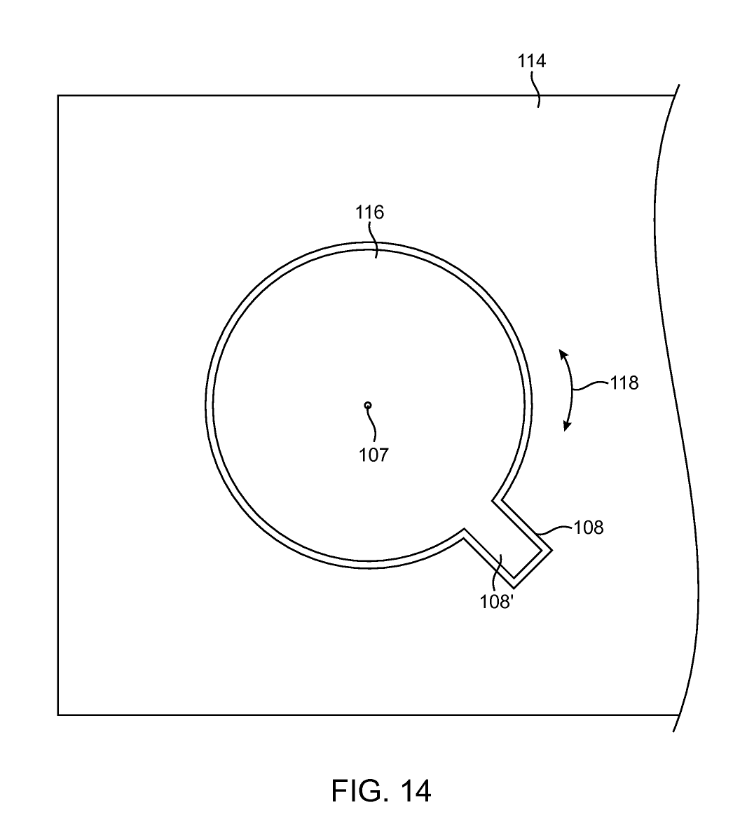

FIG. 14 is an end view of plug 116 in a configuration in which plug 116 has been plugged into connector 14 so that rotational alignment structures 108′ on plug 116 are mated with rotational alignment structures 108 of connector 14 (e.g., rotational alignment structures on a portion of housing 114 associated with connector 14). When rotational alignment structures 108 and 108′ engage one another, rotational motion in directions 118 about rotational axis 107 is prevented, thereby ensuring that each of the contacts in plug 116 forms an electrical connection with only one respective contact in connector 14.

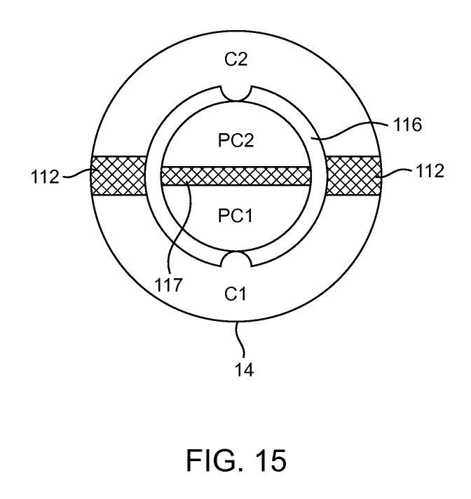

FIG. 15 is a cross-sectional end view of connector 14 in contact with plug 116, showing how contacts C1 and C2 on connector 14 may mate with corresponding contacts PC1 and PC2 on plug 116. Contacts C1 and C2 may be, for example, contacts PD and PH of FIG. 13A, whereas contacts PC1 and PC2 may be, for example, contacts TL and TR of FIG. 13A.

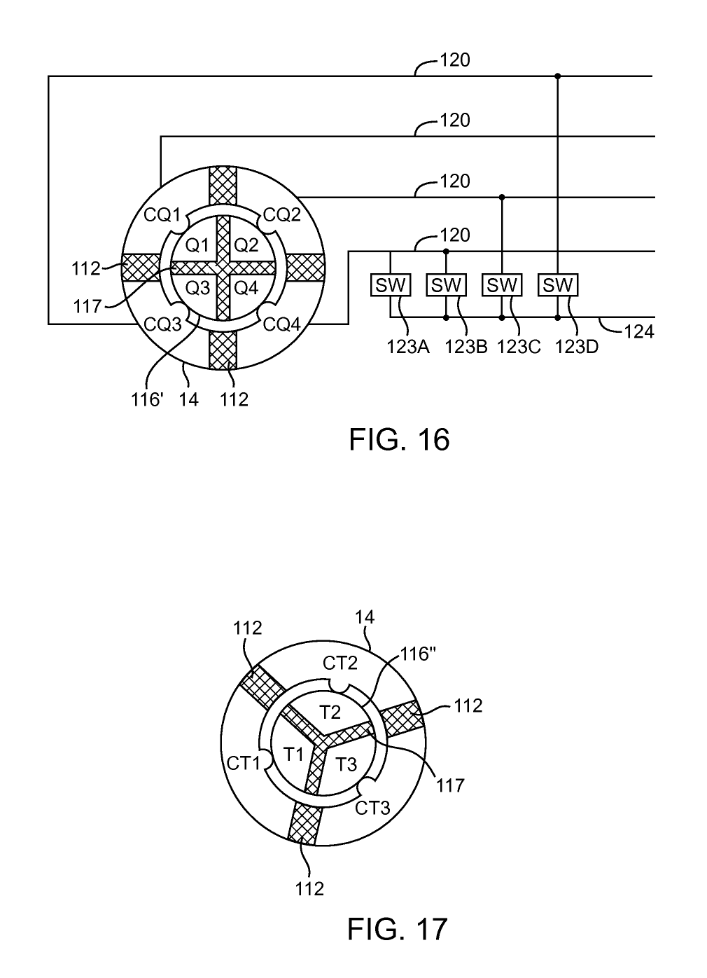

FIG. 16 is a cross-sectional end view of an illustrative rotationally asymmetric male connector and a mating rotationally asymmetric female connector. As shown in FIG. 16, connector 116′ may be an audio plug in which each longitudinally spaced contact has been segmented to form a set of four respective contacts such as contacts Q1, Q2, Q3, and Q4. Connector 14 may have a mating set of respective contacts such as contacts CQ1, CQ2, CQ3, and CQ4. There may be four contact regions along the length of each connector (i.e., a tip contact region, two ring contact regions, and a sleeve contact region for connector 116′ and a tip contact region, two ring contact regions, and a sleeve contact region for connector 14).

Each contact region in connector 116′ may be rotationally asymmetric and used to form four corresponding separate contacts and each contact region in connector 14 may be rotationally asymmetric and used to form four corresponding separate contacts. As a result, connector 116′ may have sixteen separate contacts and connector 14 may have sixteen mating contacts. Each of the sixteen contacts in connector 14 may be coupled to a respective one of lines 120. During testing, lines 120 may be routed to individual input-output pins for circuits control circuitry 38 (FIG. 8). During normal operation, switches 123A, 123B, 123C, and 123D may be closed to short lines 120 for each contact region to a common line such as line 124. Lines such as line 124 may be coupled to audio circuit 46. During normal mode operations, the sixteen separate contacts on connector 14 may be organized by the closure of switches 123A, 123B, 123C, and 123D to form four separate longitudinally spaced contacts (T, R, R, and S). During testing, switches 123A, 123B, 123C, and 123D may be opened to lines 120 to operate independently.

If desired, some of lines 120 may not be coupled to line 124 and switches 123A, 123B, 123C, and 123D associated with those lines may be omitted. In at least some arrangements, only a single line of lines 120 may be connected to line 124 during normal operations (e.g., device 12 may include switch 123A to switchably connect contact CQ4 to line 124 and switches 123B, 123C, and 123D may be omitted). This is merely illustrative and, in general, any one (and any number) of lines 120 may be switchably connected to line 124 (e.g., switchably connected to audio circuitry 46).

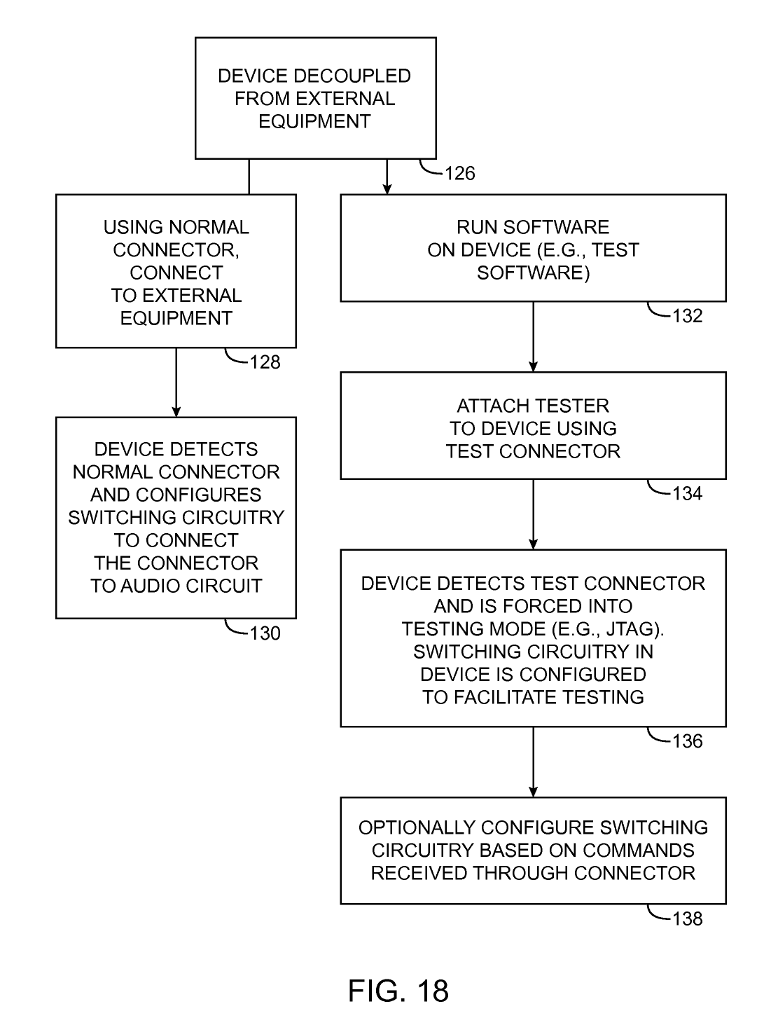

FIG. 17 is a cross-sectional view showing how plug 116″ may be provided with three contacts T1, T2, and T3 in each longitudinally spaced contact region along the longitudinal dimension of the plug. Connector 14 may be provided with three corresponding contacts CT1, CT2, and CT3 in each position along the length of connector 14. For example, plug 116″ of FIG. 17 may have three contacts associated with a tip contact region, three contacts associated with a first ring contact region, three contacts associated with a second ring contact region, and three contacts associated with a sleeve contact region. This type of arrangement may therefore provide plug 116″ with twelve separate contacts. Connector 14 may have twelve corresponding contacts. During normal operation, the contacts can be shorted together using switching circuitry 53 (e.g., switching circuits such as switches 123 of FIG. 16) or a subset of the contacts may be used to make connections with standard audio plugs. During testing, each of the twelve contacts in plug 116 and connector 14 may be used in handling different testing signals (e.g., four or five JTAG signals, etc.).

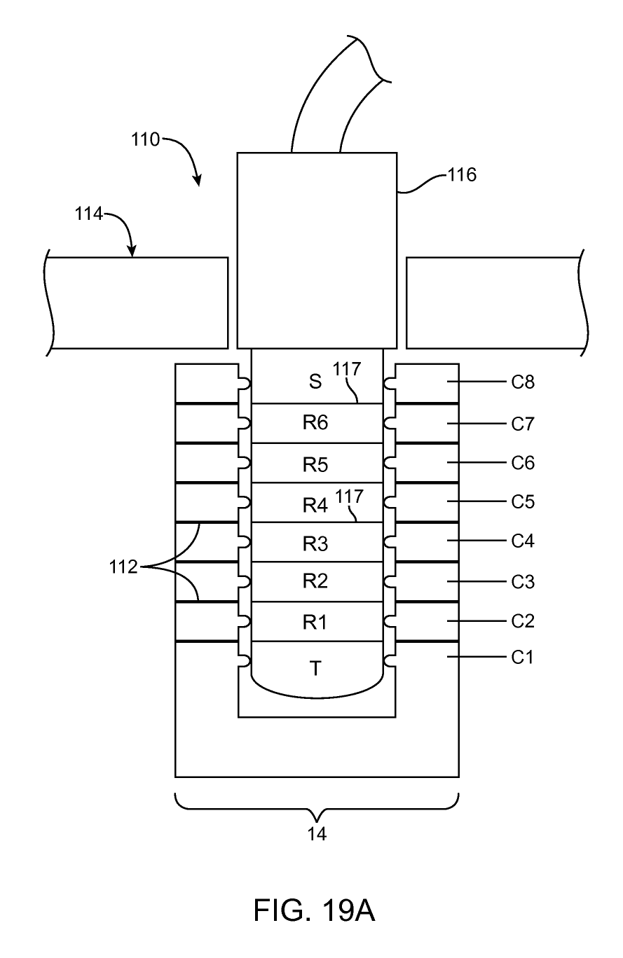

FIG. 18 is a flow chart of illustrative steps involved in using a system of the type shown in FIG. 1 where test equipment 30 has a non-standard audio plug or other such connector to invoke testing. At step 126, system 10 may be operated in a configuration in which device 12 is disconnected from external equipment 16. In this configuration, there are no mating connectors present within connector 14 of device 10.

In normal use, a user of device 12 may plug a connector into connector 14 such as a connector associated with power adapter 18 (e.g., connector 22) or a connector associated with accessory 26 (e.g., connector 24). Connectors such as connectors 22 and 24 may have standard pin-outs (e.g., pin-outs that comply with the physical form factors associated with standards-compliant TRS audio connectors, standards-compliant TRRS audio connectors, or other connectors).

During testing, test personnel may connect tester 30 to electronic device 12 by connecting connector 28 of tester 30 to connector 14. Connector 28 may be formed as part of the housing for tester 30, may be pigtailed to tester 30, or may be part of a cable that is coupled between device 12 and the equipment used to implement tester 30. Connector 28 may include features that distinguish connector 28 from standards-compliant connectors such as connectors 22 and 24. As an example, in a system configuration in which connectors 22 and 24 are four-pin audio connectors (e.g., standards-compliant TRRS connectors), connector 28 may be provided with a nonconducting tip (e.g., a missing tip or a tip coated with an insulating layer or other tip configuration that forms a nonconducting tip structure) or may be provided with segmented rotationally asymmetric contacts or other non-standards-compliant configuration.

When a user couples a standards-compliant connector to connector 14 (step 128), device 12 detects the presence of the standards-compliant connector and configures switching circuitry 52 accordingly. For example, device 12 may couple connector 14 to audio circuit 46 (FIG. 2) via path 58, switching circuitry 52, and path 60. During the normal operations of step 130, a user may use the external equipment that is coupled to connector 14. For example, a power adapter such as adapter 18 may be used in charging a battery in device 12 via connector 14. As another example, consider the use of an accessory such as a pair of headphones with an integrated microphone. When an accessory of this type is plugged into connector 14 (e.g., using a four-pin audio connector), the microphone terminal on the connector may carry microphone signals from the microphone, while the right and left audio terminals may be used to carry stereo audio signals from the audio circuit in device 12 to speakers in the headset.

To test device 12 (e.g., in a factory or other manufacturing environment, etc.), test personnel may run software on device 12. For example, at step 132, test personnel may run a test-specific version of an operating system on device 12, may run a test application on device 12, may run consumer software on device 12, or may run any other suitable software on device 12. The software that is running on device 12 during the operations of step 132 may exercise functions associated with device 12 such as input-output functions, wireless communications functions, touch screen input and output functions, button press functions, display functions, audio functions using microphones and/or speakers, other user interface functions, etc. Software may be invoked automatically and/or using manual techniques.

At step 134, test personnel or automated equipment may be used to couple connector 28 to connector 14, thereby coupling tester 30 to device 12.

At step 136, device 12 may detect the presence of tester 30. For example, device 12 may use mechanical and/or electrical sensors associated with circuitry such as monitor circuitry 54 to determine whether connector 28 has been coupled to connector 14. In response to determining that connector 28 has been connected to connector 14, switching circuitry 52 may be configured appropriately and device 12 may begin test mode operations (see, e.g., test mode 68 of FIG. 3). Device 12 may, for example, be forced into a JTAG test mode (e.g., using a four-pin or five-pin JTAG interface in configurations in which connector 28 contains a sufficient number of pins or using a two-wire interface such as a Serial Wire Debug interface for supporting JTAG tests or other testing). Forcing device 12 into test mode based on the presence of connector 28, may help ensure that device 12 can be forced into test mode regardless of whether the test software or other software running on device 12 (step 132) has frozen.

As illustrated by step 138 in FIG. 18, switching circuitry 52 may be configured based on electrical commands received through connector 28. For example, switching circuitry 52 may be configured to route JTAG signals or other testing signals to a JTAG or Serial Wire Debug interface based on patterns of one or more voltages, digital signals (e.g., digital codes), or other suitable commands. Secure protocols such as a Secure JTAG protocol or other protocols may be used to prevent unauthorized access to test functions.

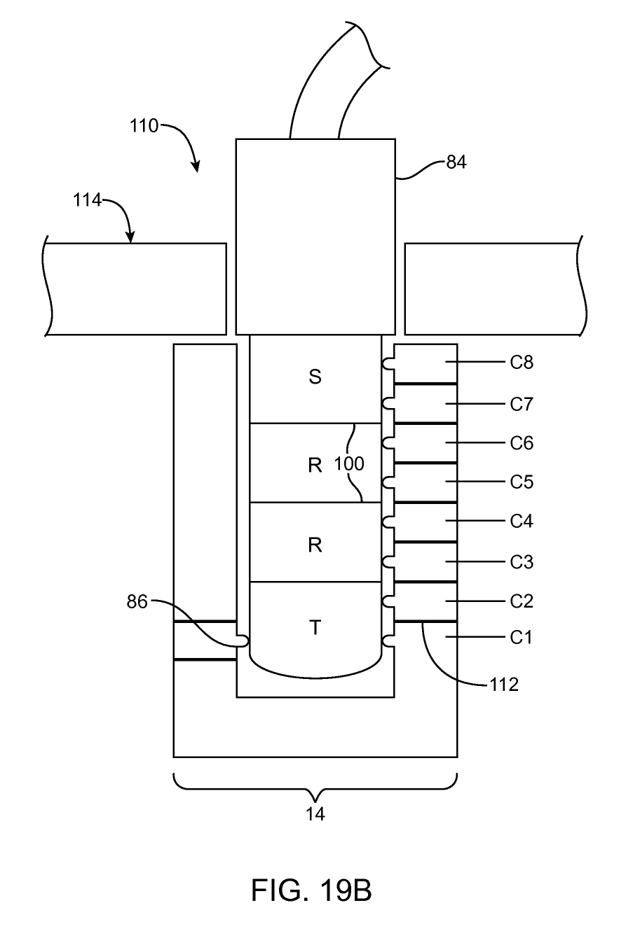

As shown in FIG. 19A, plug 116 may, in at least some arrangements, have eight contacts arranged along the length of an elongated cylindrical member and may be symmetrical. In addition, connector 14 may be configured to mate with plugs having eight contact arranged lengthwise and may also be configured to make with standards-compliant audio connectors, which have four contacts arranged lengthwise. Plug 116 may include eight contact segments such as tip contact T, ring contacts R1, R2, R3, R4, R5, and R6, and sleeve contact S. Insulator 117 may be used to separate the contact segments from each other. Connector 14 may have corresponding contacts C1, C2, C3, C4, C5, C6, C7, and C8.

As shown in FIG. 19A, connector 14 may, if desired, include a headphone detect (HPD) contact 86. Contact 86 may, in general, be formed in any desired location within connector 14.

Because there are eight independent contacts on plug 116 and eight corresponding independent contacts on connector 14 (in FIG. 19A), eight separate electrical pathways may be formed between tester 30 and device 12. These eight communications paths may be used for conveying four or five JTAG signals (and, if desired, three or four other signals), may be used for carrying Serial Wire Debug traffic, or may be used in handling other testing signals. Test connectors with more than eight separate contacts or with fewer than four contacts may also be used (e.g., male and female rotationally symmetric connectors with 2-5 contacts each, with 2-8 contacts each, with 5-8 contacts each, with more than 4 contacts each, with more than 6 contacts each, etc.).

FIG. 19B illustrates arrangements in which a connector, such as connector 84, having four contacts arranged along the length of an elongated cylindrical member is inserted into connector 14 of FIG. 19A. These arrangements may be, as an example, illustrative of arrangements in which a standards-compliant audio plug is inserted into connector 84. As shown in FIG. 19B, when a standards-compliant audio plug, which has four contacts arranged lengthwise, is inserted into connector 14 of FIGS. 19A and 19B, the tip contact of the audio plug may short together contacts C1 and C2 of connector 14, the first ring contact may short together contacts C3 and C4 of connector 14, the second ring contact may short together contacts C5 and C6 of connector 14, and the sleeve contact may short together contacts C7 and C8. Three contact standards-compliant audio plugs may similarly short out respective groupings of the contacts of connector 14. With some suitable arrangements, device 12 may not utilize signals from contacts C1, C3, C5, and C7, when a standards-compliant audio plug is inserted into connector 14.

Device 12 may include circuitry that determines when standards-compliant audio plugs are inserted into connector 14 and that determines when other plugs such as connector 116 (e.g., a connector having eight contacts) are inserted into connector 14 (e.g., by, when a plug is inserted, detecting whether contacts of connector 14 are shorted together or whether the contacts remain isolated).

The foregoing is merely illustrative of the principles of this invention and various modifications can be made by those skilled in the art without departing from the scope and spirit of the invention.

What is claimed is:

1. An electronic device, comprising:
a first circuit;
a second circuit, wherein the second circuit comprises test circuitry configured to support test mode operations;
a device connector that is configured to couple to an external connector;
switching circuitry coupled between the first and second circuits and the device connector, wherein the switching circuitry is configured to route signals from the device connector to the first circuit during normal operation and is configured to route signals from the device connector to the second circuit during the test mode operations; and
control circuitry that is configured to adjust the switching circuitry in response to detection of coupling between the external connector and the device connector.

2. The electronic device defined in claim 1 wherein the external connector comprises an audio plug with a nonconducting tip region and wherein the control circuitry is configured to adjust the switching circuitry in response to detection of the external connector with the nonconducting tip region coupled to the device connector.

3. The electronic device defined in claim 2 wherein the control circuitry is configured to adjust the switching circuitry to route signals from the device connector to the second circuit in response to detection of the external connector coupled to the device connector.

4. The electronic device defined in claim 3 further comprising at least two contacts associated with the device connector, wherein the control circuitry is configured to measure a resistance for a tip region associated with the external connector to determine whether the audio plug with the nonconducting tip is present within the device connector.

5. The electronic device defined in claim 4 wherein the second circuit comprises circuitry configured to implement Joint Test Action Group test operations.

6. The electronic device defined in claim 1 wherein the external connector comprises a rotationally asymmetric audio plug with at least one rotationally asymmetric contact region having a plurality of contacts and wherein the control circuitry is configured to adjust the switching circuitry in response to detection of the rotationally asymmetric audio plug coupled to the device connector.

7. The electronic device defined in claim 6 wherein the control circuitry is configured to adjust the switching circuitry to route signals from the device connector to the second circuit in response to detection of the external connector coupled to the device connector.

8. The electronic device defined in claim 7 further comprising at least two contacts associated with the device connector, wherein the control circuitry is configured to use the at least two contacts to measure a resistance associated with a tip portion of the external connector to determine whether the rotationally asymmetric audio plug is present within the device connector.

9. The electronic device defined in claim 8 wherein the second circuit comprises circuitry configured to implement Joint Test Action Group test operations.

10. A method of performing testing on an electronic device that contains a first circuit, a second circuit, an audio connector, switching circuitry coupled between the first and second circuits and the audio connector, and control circuitry, wherein the second circuit supports operation in a test mode, the method comprising:
with the control circuitry, detecting whether a test connector that is associated with a tester has been inserted within the audio connector; and
in response to detection of the test connector within the audio connector, performing operations in the test mode with the second circuit.

11. The method defined in claim 10 wherein the audio connector comprises a female audio connector, wherein the test connector comprises a male audio connector with a nonconducting tip region, and wherein detecting whether the test connector has been inserted within the audio connector comprises measuring a resistance associated with the nonconducting tip region using the control circuitry.

12. The method defined in claim 11 wherein performing the operations in the test mode comprises performing Joint Test Action Group test operations.

13. The method defined in claim 11 wherein performing the operations in the test mode comprises performing Serial Wire Debug test operations.

14. The method defined in claim 10 wherein the second circuit is configured to support Universal Asynchronous Receiver Transmitter communications and Universal Serial Bus communications, the method further comprising using the second circuit to convey Universal Asynchronous Receiver Transmitter data and Universal Serial Bus data through the audio connector.

15. The method defined in claim 10 wherein the audio connector comprises a female audio connector, wherein the test connector comprises a rotationally asymmetric male audio connector with at least one segmented rotationally asymmetric contact region, and wherein detecting whether the test connector has been inserted within the audio connector comprises measuring a resistance associated with the segmented rotationally asymmetric contact region using the control circuitry.

16. The method defined in claim 15 wherein the electronic device comprises a housing and wherein the female audio connector is mounted within the housing, the method further comprising:
connecting the male audio connector to the female audio connector so that rotational alignment features associated with the male and female audio connectors engage and rotationally align the male audio connector with respect to the female audio connector.

17. A male audio test connector adapted to mate with a female audio connector in a device, comprising:
an elongated member extending between first and second ends; and
a plurality of contacts arranged along the elongated member, wherein the elongated member is configured to form a nonconducting tip structure at the first end.

18. The male audio test connector defined in claim 17 wherein the plurality of contacts include a sleeve contact and at least one ring contact and no tip contact.

19. A male audio test connector adapted to mate with a female audio connector in a device under test, comprising:
an elongated cylindrical member extending between first and second ends; and
a plurality of segmented rotationally asymmetric contact regions each of which forms a set of multiple contacts, wherein each set of multiple contacts is arranged at a different longitudinal position along the elongated cylindrical member.

20. The male audio connector defined in claim 19 wherein the plurality of contacts includes at least eight contacts.
